(19) United States
(12) Patent Application Publication
(10) Pub. No.: US 2025/0138476 A1
(43) Pub. Date: May 1, 2025

(54) REPLICATION OF A MASTER HOLOGRAPHIC OPTICAL ELEMENT WITH VARIABLE ILLUMINATION

(71) Applicant: Carl Zeiss Jena GmbH, Jena (DE)

(72) Inventors: Markus GIEHL, Jena (DE); Andre MAGI, Jena (DE); Isabelle MARET, Jena (DE)

(73) Assignee: Carl Zeiss Jena GmbH, Jena (DE)

(21) Appl. No.: 18/835,587

(22) PCT Filed: Feb. 6, 2023
(86) PCT No.: PCT/EP2023/052828

§ 371 Date: Aug. 2, 2024

(30) Foreign Application Priority Data
Feb. 4, 2022 (DE) 102022102646.9

(51) Int. Cl. G03H 1/04

(52) U.S. Cl. CPC G03H 1/0402; G03H 2001/0439

(57) ABSTRACT

The invention relates to techniques for producing an HOE by replication of a master HOE. In particular, techniques that allow variable surface shape during replication are described. A curved trajectory is used for exposure.

### RELATED APPLICATIONS

The present application is a National Phase patent application of PCT Appl. No. PCT/EP2023/052828, filed on Feb. 6, 2023, which claims priority to German Patent Appl. No. DE102022102646.9, filed on Feb. 4, 2022, each of which is hereby fully incorporated herein by reference.

### FIELD OF THE INVENTION

Various examples concern techniques for producing a holographic optical element (HOE) by replicating a master HOE. Various examples concern in particular techniques for variably adapting the illumination of the master HOE during replication.

### BACKGROUND OF THE INVENTION

HOEs are used in various fields of application. For example, HOEs can be used to implement a transparent screen. Fields of application concern, for example, the use in a head-up display in an automobile or the integration of a holographic optical element in a mirror. HOEs are used for generating holograms: the HOE is illuminated for this purpose; with the result that the hologram is reconstructed.

One technique for producing HOEs is based on the use of a master HOE, which is used in an exposure process of the HOE to form the HOE. In this case, the carrier layer (for example a photopolymer, which is arranged on a substrate) of the master HOE is arranged along the carrier layer of the HOE to be replicated (hereinafter simply “replicated HOE”). With exposure, the diffraction structure of the master HOE can then be replicated in the replicated HOE.

Such production methods which use replication of the master HOE for the production of the HOE can use a roll-to-roll process, for example, in which the master HOE and the HOE are arranged on a respective roll as fixing element, which rolls are rotated synchronously with one another, so that a partial region of the master HOE extends in each case along a corresponding partial region of the replicated HOE. Another technique is the flatbed process, in which the master HOE and the replicated HOE are fixed on a respective planar or flat carrier, so that the entire surfaces of the respective carrier layers extend along one another.

In such production methods, the surface shape of the carrier layer of the master HOE and of the HOE during the replication process is predefined by the technical boundary conditions of this process. By way of example, the master HOE is one-dimensionally curved in the roll-to-roll process; whereas the master HOE is arranged in planar fashion in the flatbed process. This pre-definition of the surface shape makes it more difficult to produce HOEs which are intended to be fixed after the exposure process upon application in arbitrary surface shapes, for example on account of boundary conditions of the field of application. Some fields of application may require the HOE to be integrated into curved surfaces, for example on account of the limited installation space, etc.

### SUMMARY OF THE INVENTION

There is a need for improved production methods for HOEs. In particular, there is a need for improved production methods that enable a flexible surface shape of HOEs in the application. There is a need to produce HOEs with high quality.

A method for producing a replicated HOE by replicating a master HOE in the context of an exposure process is disclosed. During the exposure process, in this case, a carrier layer of the master HOE is arranged along a carrier layer of the replicated HOE. The method comprises controlling a radiation source in order to emit light onto the master HOE during the exposure process, with the result that the HOE is exposed. The master HOE is replicated. Moreover, the method comprises controlling a positioning module in order to move a reference point, which is arranged along a beam path of the light, in relation to the master HOE on a trajectory during the exposure process.

The trajectory thus denotes a path along which a point along the beam path of the light is moved. The beam path of the light can be fixed in relation to this reference point, i.e. can run through the reference point by provision of a corresponding optical element at the reference point. At different points in time, the reference point is situated at different positions along the trajectory.

A point light source can be arranged at the reference point. An emitter of the light source can be arranged at the reference point. Alternatively, the emitter of the light source can be arranged further upstream; and the light emitted by the emitter can be focused at the reference point, for example. The light emitted by the emitter can be collimated. The collimated beam path can run through the reference point.

The reference point can thus denote that point along the beam path at which the positioning module acts on the beam path of the light in a time-variant manner. The beam path is linked with the reference point and is guided and/or directed at the reference point. At the reference point, the positioning module can tilt and/or deflect and/or translationally offset and/or rotate the beam path in a time-variant manner, for example.

The reference point can be arranged downstream of the radiation source. However, the radiation source could also be arranged at the reference point; i.e. the reference point would be arranged right at the beginning of the beam path.

In addition, an optical element can be provided which acts on the beam path at the reference point in a time-invariant manner; for example, the beam path can be expanded or collimated.

The trajectory can be curved (i.e. in a global coordinate system of a corresponding apparatus). The trajectory can be straight.

The trajectory can extend within a plane. The trajectory can also extend in three-dimensional space.

The trajectory can comprise a component perpendicular to the carrier layer of the master HOE and to the carrier layer of the replicated HOE.

The radiation source can emit light in the visible spectrum, for example. Radiation in the ultraviolet or infrared range of the electromagnetic spectrum could also be emitted. The radiation source can be a coherent laser light source. By way of example, the radiation source could have one or more channels, at different wavelengths. For example, the radiation source could have 3 channels, for instance red-green-blue.

The radiation source can be embodied as a point source. That means that an emitter area is particularly small. Typical emitter areas can have edge dimensions of less than 1 mm or less than 100 μm or less than 50 μm.

A corresponding optical system can be used to form a light point of the light on the master HOE. That means that the master HOE is not illuminated over a large area, but rather is illuminated gradually by moving the light point. The movement of the light point is achieved in particular by the movement of the reference point on a trajectory.

The master HOE can be formed in a photopolymer which is part of the carrier layer. The carrier layer could also additionally comprise a substrate. The carrier layer could be film-based. A so-called volume HOE could be used.

The HOE can be formed in a photopolymer which is part of the corresponding carrier layer. The carrier layer could also additionally comprise a substrate. The carrier layer could be film-based. A so-called volume HOE could be used.

By replication, a diffraction structure of the master HOE can be copied in the HOE. The HOE is exposed for the purpose of replication. This typically causes chain formation of polymers. The diffraction structure corresponds to a local variation in the refractive index, for example due to different chain lengths or a different degree of chain formation of polymers in a corresponding layer. When the diffraction structure is illuminated, the hologram is reconstructed. Hereinafter, the terminology “exposure” or “expose” is used in connection with the replication of the master HOE during generation of the HOE; whereas the terminology “illumination” or “illuminate” is used in connection with the use of an already produced HOE for the reconstruction of a hologram.

The use of the positioning module can enable a variable angle of incidence of the light on the master HOE (and thus on the replicated HOE) during the exposure process. In particular, it is possible to vary the angle of incidence of the light as a function of the location of a corresponding light point of the light on the master HOE. That means that the positioning module is configured to move a light point of the light of the radiation source over the carrier layer of the HOE (or the master HOE). Different angles of incidence are realized for different positions of the light point. This is made possible for example by a suitable trajectory, for instance by a suitable curvature. Alternatively or additionally, suitable scanning patterns can be used. What is achieved by such techniques is compensation of a curvature of the carrier layer of the master HOE during the exposure process, which curvature is predefined on the basis of the production process and deviates from the surface shape in the intended field of application. To put it another way, it is thus possible to compensate for a curvature of the carrier material of the master HOE during the exposure process (where this curvature is defined e.g. in relation to a reference coordinate system defined by the shape of the carrier material of the master HOE during the production of the master HOE).

Use of the positioning module can enable in particular variable curved trajectories (“freeform trajectories”). That means that different curved trajectories can be implemented depending on the control of the positioning module. This is made possible by corresponding degrees of freedom of the movement of the positioning module. As a result, it is possible to compensate for different curvatures of the master HOE during the exposure process.

Different implementations for the reference point are conceivable depending on the implementation of the positioning module and associated optics. By way of example, the reference point could correspond to a focus point of the light along the beam path, that is to say that the light can have a smaller beam cross-section at the focus point compared with downstream or upstream along the beam path. Alternatively or additionally, the reference point could be coincident with the arrangement of a lens element or a mirror which implements a last beam deflection before the light is incident on the master HOE.

In some examples, a beam deflection of the beam path at the reference point could also be set besides a movement of the reference point along the e.g. curved trajectory by means of the positioning module.

As a result, it is possible to achieve different scanning patterns for the movement of a light point for the exposure of the HOE.

In one example, this beam deflection can be set by the movement of the reference point; that means: by shifting the reference point with respect to the light source, it is possible to achieve a different beam deflection. That means, in other words, that the position of the reference point and the beam deflection cannot be set separately from one another.

In other examples, however, it would also be conceivable that the beam deflection can be set independently of the movement of the reference point. For this purpose, for example, an optical element such as, for example, a lens element or a deflection mirror or a prism can be arranged in a tiltable fashion at the reference point in order in this way to change the emergence angle of the beam path at the reference point along the curved trajectory in relation to the master HOE.

This additional degree of freedom concerning the orientation of the beam path in relation to the reference point makes it possible to further vary the angle of incidence of the light on the master HOE during the exposure process. Flexible scanning patterns can be implemented.

By way of example, such a variation of the emergence angle of the beam path at the reference point could be effected step by step by means of the positioning module. A mirror could be tilted step by step. The emergence angle of the beam path at the reference point could be changed by way of tilting using a corresponding motorized joint.

Such a variation of the emergence angle of the beam path at the reference point by means of the positioning module can be superimposed by a scanning movement of the beam path. The reference point could be defined for example as the center of the scanning movement. The scanning movement can correspond to a periodic movement around a scanning midpoint. The mid-point can correspond to the reference point. In connection with the scanning movement, it is thus possible to define a scanning frequency and a scanning amplitude.

By way of example, the method could furthermore comprise controlling a scanning mirror in order to scan the light in relation to the master HOE during the exposure process.

The use of the scanning mirror makes it possible to scan the light point over an extensive region of the master HOE in order in this way to illuminate all regions of the master HOE in the context of the exposure process. A scanning pattern is used for this purpose.

As a general rule, a local irradiance (expressed in watts per square meter, for example) integrated over the exposure process could vary as a function of the position on the master HOE by not more than plus minus 20 percent, optionally by not more than plus minus 5 percent. The same can correspondingly apply to the dose together with the residence duration of the light point on the different positions of the master HOE.

In particular, a scanning direction during the scanning of a light point of the light on the master HOE during the exposure process can have a component which is orthogonal to a movement direction of the light point of the light on the master HOE which is caused by the movement of the reference point along the curved trajectory.

In other words, the light point of the light on the master HOE as a result of the movement of the reference point along the e.g. curved trajectory could be moved principally from left to right (in an arbitrarily defined reference system); whereas the light point of the light on the master HOE as a result of the scanning is moved principally from top to bottom. As a result, a substantially homogeneous irradiation or exposure integrated over the exposure process can be attained; at the same time, however, a flexible compensation of different surface shapes of the carrier layer of the HOE during the exposure process and in the subsequent application can be made possible.

By means of the combination of the movement along the e.g. curved trajectory (and optionally a change of the emergence angle by means of the positioning module), firstly, and the scanning, secondly, the angle of incidence of the light on the master HOE can thus be varied flexibly. Moreover, it is possible to attain an integrated irradiation that is as homogeneous as possible in the different regions of the master HOE during the exposure process. Accordingly, it is possible to flexibly adapt the scanning amplitude and/or the scanning frequency. By way of example, the scanning amplitude could be adapted such that the light point of the light during the scanning moves in each case from edge to edge of the master HOE. This corresponds e.g. to a Cartesian scanning pattern with scan lines. Together with a variable scanning amplitude, the scanning frequency can be adapted so that the residence duration of the light point in the different regions along a scan line remains constant independently of the scanning amplitude; a homogeneous integrated irradiation in the different regions of the master HOE during the exposure process can be made possible as a result.

In one simple variant, it would be conceivable for the master HOE to be arranged during the exposure process such that the scanning frequency and optionally the scanning amplitude can remain constant during the exposure process. By way of example, the master HOE could be arranged with a specific fixed transverse extent such that this fixed transverse extent is swept over by the scanning of the light point with a fixed scanning amplitude and scanning frequency.

The scanning mirror could be arranged at the reference point. However, it would also be conceivable for the scanning mirror to be arranged offset with respect to the reference point, in particular upstream along the beam path. It would be conceivable for the scanning mirror to be arranged at a focus point of the beam path. If the scanning mirror is arranged at the focus point of the beam path, comparatively small mirror surfaces can be sufficient; this enables higher scanning frequencies because the moved mass and thus the required forces or dynamic deformations decrease.

Various implementations of the scanning mirror are conceivable. By way of example, a scanning mirror with a galvanometer drive could be used, i.e. a so-called galvanometer mirror. A mirror implemented in microelectromechanical form (MEMS) could also be used. A polygon scanning mirror could be used. An acousto-optic deflector could also be used.

The scanning mirror can have one or more degrees of freedom of the scanning movement. For example, one-dimensional or two-dimensional scanning could be made possible.

The scanning mirror could be a two-dimensionally tiltable scanning mirror of the positioning module. In such a scenario, the scanning mirror could be controlled in order-in a manner superimposed with the scanning-additionally to change the emergence angle of the beam path at the reference point in relation to the master HOE. Such a change of the emergence angle can take place particularly slowly in comparison with the scanning.

A description has been given above of techniques for exposing the HOE by illuminating the master HOE when the corresponding carrier materials are arranged next to one another.

In various examples, the method can also comprise producing the master HOE in a further (upstream) exposure process. In such a further exposure process for producing the master HOE, the carrier layer of the master HOE is typically fixed in a surface shape corresponding to the surface shape of the replicated HOE in the application situation. It is thus possible for the carrier layer of the master HOE during the further exposure process to have a first surface shape, which is different than a second surface shape of the carrier layer during the exposure process.

In this regard, it would be conceivable, for example, for the first surface shape (during exposure of the master HOE for producing the master HOE) to correspond to a one-dimensional curvature of the carrier layer; and the second surface shape (during illumination of the master HOE for exposure and production of the replicated HOE) to correspond to a planar embodiment of the carrier layer, that is to say without curvature, of the master HOE. This would be possible in particular for a flatbed replication process.

In another example, it would be conceivable for the first surface shape (during exposure of the master HOE for producing the master HOE) to be planar; and the second surface shape (during illumination of the master HOE for exposure and production of the replicated HOE) to correspond to a one-dimensional curvature of the carrier layer. That would be possible for example in a roll-to-roll replication process.

This means that only a one-dimensional change of the curvature of the carrier layer needs to be compensated for in such cases by a suitable choice of the e.g. curved trajectory and/or the angle of incidence of the light during the illumination of the master HOE for exposure and production of the replicated HOE.

In such an example, the scanning direction of the scanning movement caused by the scanning mirror can run perpendicular to the axis of the one-dimensional curvature.

As a general rule, it is not necessary in all variants to use a scanning mirror for scanning during the exposure process. By way of example, in some scenarios, it would be conceivable for one or more optical elements (e.g. lens elements and/or mirrors, for instance dichroic mirrors) to be arranged at the reference point along the beam path, which cause the light point of the light on the master HOE to be expanded (that is to say in relation to a case in which the at least one lens element were not present). By way of example, such an expansion could take place one-dimensionally along one axis-which would be scanned for example in another implementation scenario. By way of example, such an expansion of the light point could take place in such a way that the light point covers the entire transverse extent of the master HOE.

In some examples, a combination of at least one expanding optical element, as described above, with a scanning mirror would also be conceivable.

In principle, various implementations are conceivable for the positioning module. For example, the positioning module could comprise a robotic arm with a plurality of adjustable axes. It would also be conceivable for the positioning module to comprise a multi-axis optical linear adjustment table. An adjustment table could optionally also have a rotational degree of freedom. Generally, the positioning module can comprise one or more actuators which address different degrees of freedom of the adjustment of the positioning module in order in this way to enable the curved trajectory and/or a change of the emergence angle.

The positioning module can be controlled in a computer-implemented manner.

By way of example, the positioning module can be controlled on the basis of control data determining the e.g. curved trajectory and/or optionally also the emergence angle of the light at the reference point in relation to the master HOE.

With the aid of the control data, it is possible to determine the angle of incidence of the light on the master HOE.

With the aid of the control data, the scanning pattern or the angle of incidence of the light for replication of the master HOE during exposure of the HOE is determined as a function of the position of the light point on the carrier layer.

In some examples, it would also be conceivable for the control data to specify the angle of incidence of the light on the master HOE, i.e. as a function of the position of the light point on the carrier layer; the angle of incidence of the light on the master HOE may then be translated into a suitable movement of the positioning module by means of a corresponding logic-which typically depends on the architecture of the positioning module. That means, therefore, that the control data can specify/indicate the angle of incidence of the light on the master HOE.

In some examples, the method can also comprise calculating the control data. For example, the control data could be calculated on the basis of a first surface shape of the carrier material of the master HOE during the further exposure process for exposing the master HOE, and on the basis of a second surface shape of the carrier material of the master HOE during the exposure process (for exposing the replicated HOE), and further on the basis of the angle of incidence of light as a function of the location on the master HOE during the further exposure process.

When calculating the control data, it is also possible to take account of the emitter geometry of a light source which is used later when reconstructing the hologram by illumination of the HOE. In this way, for example, areal light sources for illuminating the HOE when reconstructing the hologram can also be made possible, whereas a non-areal light source (or generally a light source with a different emitter geometry) is used when replicating the master HOE.

When calculating the control data, it is possible to take account of a deformation of the diffraction structure of the master HOE on account of a change of the surface shape. A changed diffraction pattern results on account of the deformation of the diffraction structure. This changed diffraction structure of the master HOE during the exposure process for exposing the replicated HOE is copied to the replicated HOE. That means that if the replicated HOE is fixed after the exposure processes with respect to a different surface shape—typically the first surface shape present during exposure of the master HOE—the inverse change of the surface shape is present and so, too, is an inverse change of the diffraction pattern. The replicated HOE can then be illuminated in a flexible surface shape. It is possible to use various light sources for the illumination, e.g. including extensive light sources.

In order to compensate for this change of the surface shape (or the inverse change of the surface shape), the angle of incidence of the light can be correspondingly adapted during exposure of the replicated HOE. This is suitably stored in the control data.

Such a calculation of the control data can typically take place for example during production of the master HOE. The control data can then be stored in a corresponding database or lookup table.

It is possible to take account of various input variables in the calculation of the control data. By way of example, it is possible to take account of the surface shape of the HOE during exposure and the surface shape of the HOE during illumination for reconstructing the hologram. It is also possible to take account of the illumination geometry or emitter geometry during illumination. That means that an arrangement of the light source used for illumination when reconstructing the hologram with respect to the HOE can be taken into account; and so, too, can an extent of the light source. It is possible to anticipate and correct aberrations, for instance on account of material expansion, etc.

It would be conceivable for the control data to be selected from a control data lookup table, depending on the master HOE used. In this case, the control data lookup table can comprise a multiplicity of candidate control data associated with different master HOEs. In such a scenario, it is thus possible to use different control data depending on the master HOE-thus typically also depending on the intended surface shape for the replicated HOE.

Techniques for producing the replicated HOE have thus been described above. After the exposure process for replicating the master HOE, the carrier layer of the replicated HOE can then be fixed in a surface shape that is different than the surface shape of this carrier layer during the exposure process for the replicated HOE.

A computer program comprises program code that can be loaded and executed by a processor. When the processor executes the program code, this causes the processor to carry out a method for producing a HOE by replicating a master HOE in the context of an exposure process. During the exposure process, a carrier layer of the master HOE is arranged along a carrier layer of the HOE. The method comprises controlling a radiation source in order to emit light onto the master HOE during the exposure process, with the result that the HOE is exposed. Moreover, the method comprises controlling a positioning module in order to move a reference point, which is arranged along a beam path of the light, in relation to the master HOE on a curved trajectory during the exposure process.

A data processing unit comprises at least one processor and a memory. The at least one processor is configured to load and execute program code from the memory. This causes the at least one processor to carry out a method for producing a HOE by replicating a master HOE in the context of an exposure process. During the exposure process, a carrier layer of the master HOE is arranged along a carrier layer of the HOE. The method comprises controlling a radiation source in order to emit light onto the master HOE during the exposure process, with the result that the HOE is exposed. Moreover, the method comprises controlling a positioning module in order to move a reference point, which is arranged along a beam path of the light, in relation to the master HOE on a curved trajectory during the exposure process.

A device (can also be referred to as an exposure system) for producing a HOE comprises at least one fixing element on which a carrier layer of a master HOE and a carrier layer of the HOE can be arranged during an exposure process, with the result that these extend at least locally along one another. The device also comprises a radiation source configured to emit light onto the master HOE during the exposure process, with the result that the HOE is exposed. Moreover, the device also comprises a positioning module configured to move a beam path of the light during the exposure process relatively in relation to the carrier layer of the master HOE and the carrier layer of the HOE.

A data processing unit comprises at least one processor and a memory. The at least one processor is configured to load and execute program code from the memory. The at least one processor is also configured, on the basis of the program code, to calculate control data for the control of a device for replicating a master HOE or for exposing a HOE.

Corresponding program code that can be executed by at least one processor is also disclosed. When the at least one processor executes the program code, this causes the at least one processor to calculate control data for the control of a device for replicating a master HOE or for exposing a HOE.

The features set out above and features that are described hereinbelow can be used not only in the corresponding combinations explicitly set out, but also in further combinations or in isolation, without departing from the scope of protection of the present invention. By way of example, techniques in connection with a method for producing a HOE by replicating a master HOE have been described above. Corresponding methods and techniques can be implemented by a device or an exposure system, as described above. Moreover, techniques in connection with the use of control data for controlling one or more components of such a device have been described above. Corresponding techniques can be combined with a data processing unit configured for calculating corresponding control data.

### BRIEF DESCRIPTION OF THE DRAWINGS

FIG. 1 is a flowchart of one exemplary method for producing a HOE.

FIG. 2 schematically illustrates a system for exposing a HOE in the context of a replication of a master HOE in accordance with various examples.

FIG. 3 schematically illustrates a variation of the system from FIG. 2.

FIG. 4 schematically illustrates the illumination of a master HOE in a target surface shape in accordance with various examples.

FIG. 5 schematically illustrates the illumination of a master HOE in an exposure surface shape that deviates from the target surface shape, in accordance with various examples.

FIG. 6 is a flowchart of one exemplary method.

FIG. 7 schematically illustrates a flatbed replication process for exposing a HOE by replication of a master HOE in accordance with various examples.

FIG. 8 schematically illustrates a roll-to-roll replication process for exposing a HOE by replication of a master HOE in accordance with various examples.

FIG. 9 schematically illustrates a master HOE with a one-dimensionally curved target surface shape in accordance with various examples.

FIG. 10A schematically illustrates the master HOE from FIG. 9 with a planar illumination surface shape in accordance with various examples.

FIG. 10B is a side view of the master HOE from FIG. 10A.

FIG. 10C is a further side view of the master HOE from FIG. 10A.

FIG. 11 schematically illustrates a HOE with a one-dimensionally curved surface shape and an areal illumination for replicating a hologram in accordance with various examples.

FIG. 12A corresponds to FIG. 11, with virtual point light sources being shown as replacement for the areal illumination.

FIG. 12B schematically illustrates the HOE from FIG. 11 during exposure in accordance with various examples.

FIG. 13 illustrates aspects in connection with a positioning module in accordance with various examples.

FIG. 14 illustrates aspects in connection with a positioning module in accordance with various examples.

FIG. 15 illustrates aspects in relation to a roll-to-roll replication process in accordance with various examples.

FIG. 16 illustrates aspects in connection with a roll-to-roll replication process in accordance with various examples.

FIG. 17 shows a side view of a HOE during replication in accordance with various examples.

FIG. 18 corresponds to FIG. 17, with a spherical aberration being present.

FIG. 19 shows the exposure of a master HOE for replication with compensation of a spherical aberration in accordance with various examples.

FIG. 20 schematically illustrates a data processing unit in accordance with various examples.

### DETAILED DESCRIPTION OF THE INVENTION

The properties, features and advantages of this invention described above and the way in which they are achieved will become clearer and more clearly understood in association with the following description of the exemplary embodiments which are explained in greater detail in association with the drawings.

The present invention is explained in greater detail below on the basis of preferred embodiments with reference to the drawings. In the figures, identical reference signs denote identical or similar elements. The figures are schematic representations of various embodiments of the invention. Elements illustrated in the figures are not necessarily illustrated as true to scale. Rather, the various elements illustrated in the figures are rendered in such a way that their function and general purpose become comprehensible to a person skilled in the art. Connections and couplings between functional units and elements illustrated in the figures can also be implemented as an indirect connection or coupling. A connection or coupling can be implemented in a wired or wireless manner. Functional units can be implemented as hardware, software or a combination of hardware and software.

Techniques for producing HOEs are described below. For example, volume HOEs or surface HOEs can be produced by means of the techniques described herein.

The techniques described herein are based on replicating a master HOE to produce a replicated HOE. For the production of the master HOE, a corresponding exposure process can be used upstream thereof. Various examples described herein concern in particular the exposure of the replicated HOE by replicating the master HOE.

Various examples are based on the insight that different fields of application require the integration of HOEs in curved surfaces. That means that, depending on the field of application, a carrier layer of the replicated HOE is fixed in a curved surface shape. For this purpose, the carrier layer of the replicated HOE could be applied for example to a corresponding carrier produced for example in an injection molding method or by means of additive manufacturing. The corresponding curvature of the surface shape can be one-dimensional or two-dimensional.

In such a case, the master HOE can be exposed in a state in which the carrier layer of the master HOE has the same surface shape which the replicated HOE has in the application situation. This surface shape is called target surface shape hereinafter because it is the intended surface shape after the end of the production method for the replicated HOE.

During the production method for the replicated HOE, it may however be necessary on account of technical limitations to deviate from the target surface shape. In particular, it may be conceivable that the surface shape of the carrier material of the replicated HOE during replication, that is to say during exposure of the replicated HOE, deviates from the target surface shape. This surface shape of the carrier material of the replicated HOE during replication, that is to say during exposure of the replicated HOE, is referred to hereinafter as exposure surface shape.

By way of example, a roll-to-roll process or a flatbed copying method requires specific exposure surface shapes. That means that in the roll-to-roll process or in the flatbed copying method, for example, the exposure surface shape of the replicated HOE (and accordingly of the master HOE) can be predefined and can deviate in particular from the target surface shape.

Besides such a deviation—governed by the system integration of the HOE—between the surface shape during exposure and the surface shape during illumination for reconstructing the hologram, an illumination geometry or emitter geometry which is governed by the system integration and deviates from the illumination geometry or emitter geometry during exposure can alternatively or additionally also occur during illumination for reconstructing the hologram. By way of example, a point light source can be used during the exposure. A light point can be moved over the carrier material of the HOE for the exposure. An extensive light source can be used during illumination. That means that an emitter area of the light source during illumination is significantly larger than an emitter area of the radiation source during exposure. By way of example, the emitter area of the light source during illumination can be at least a factor of 1000 larger than the emitter area of the radiation source during exposure. The light source during illumination can also comprise an array of individual emitters, e.g. a light emitting diode panel (i.e. e.g. an array of light emitting diodes or more generally an arrangement of a plurality of light emitting diodes on a carrier). Such illumination geometries governed by the system integration of the HOE can also be taken into account in the exposure.

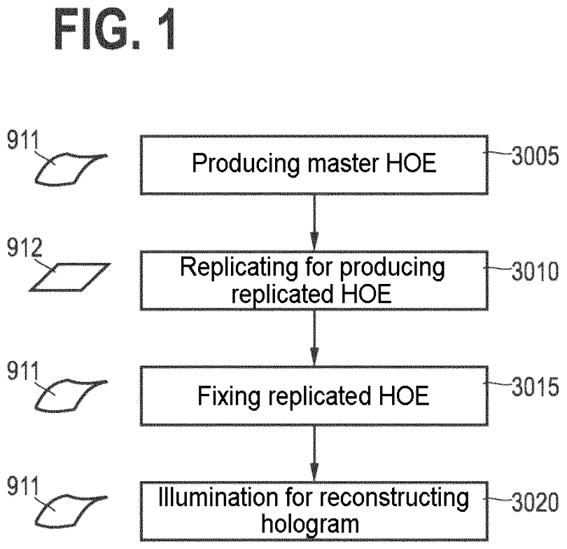

FIG. 1 illustrates a method for producing a replicated HOE in accordance with various ex- amples.

A master HOE was produced in box 3005. For this purpose, a corresponding photopolymer is exposed, which is located in or on a carrier layer of the master HOE. For the exposure, an object beam and a reference beam of corresponding light can be used, which are formed phase-coherently with respect to one another. An analogue exposure could be performed, in which the object generates the object beam. A digital exposure with a pixelated light modulator and a stitching method could also be used.

FIG. 1 shows that the master HOE (or more precisely the carrier material of the master HOE) in box 3005, that is, when the master HOE is exposed, has the target surface shape 911. This target surface shape 911 is schematically illustrated in FIG. 1 as curved by way of example but could have any shape.

Then, in box 3010, the replicated HOE is exposed by replicating the master HOE. A roll-to-roll process or a flatbed copying process can be used.

In box 3010, a laser is typically used as radiation source. The laser beam can be scanned. A light point of the laser beam can be moved over the surface of the carrier layer in which the HOE is generated.

In box 3010, the carrier material of the master HOE and the carrier material of the replicated HOE have an exposure surface shape 912; this is illustrated as planar by way of example in FIG. 1, but could also have a curvature.

The exposure surface shape 912 is different than the target surface shape 911.

After the exposure process, the carrier layer of the replicated HOE is fixed again in the target surface shape 911, box 3015. A system integration is effected for a target application, for example in a motor vehicle. Afterward, the replicated HOE can be illuminated by a suitable light source, with the result that the hologram is reconstructed, box 3020.

The replicated HOE can then be illuminated in order to reconstruct a hologram. The illumination can be effected by an arbitrary light source, e.g. a point light source or an areal light source. Put generally, in certain examples the light source used for illumination deviates from the radiation source used for exposure.

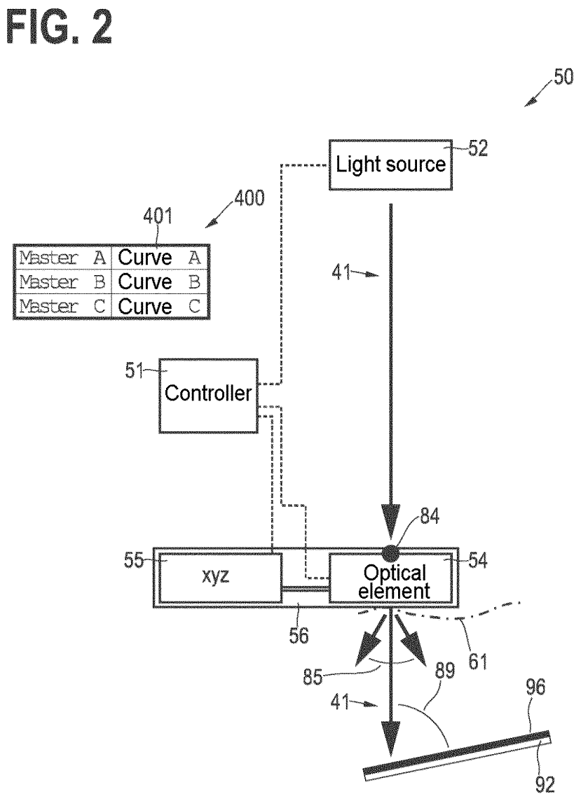

FIG. 2 illustrates aspects in connection with a device or a system 50 which can be used to produce a replicated HOE 96. The system 50 can therefore be used in particular in connection with box 3010 in accordance with the method from FIG. 1. The system 50 may be referred to as an exposure system or exposure device.

The system 50 comprises a radiation source or light source 52, for example a laser, which emits coherent laser light along a beam path 41. The “light” can be in the visible spectrum or adjacent wavelength ranges, for example in the infrared or ultraviolet part of the electromagnetic spectrum. The light source 52 is controlled by a controller 51 (for example a processor which can load and execute program code from a memory; or an application-specific integrated circuit; or a field programmable array).

The light source 52 can be a point source. That means that an emitter area of the light source 52 is particularly small. By way of example, edge dimensions of the emitter area could be <1 mm or less than 100 μm or less than 20 μm. The light source 52 can comprise collimator optics that reduce the divergence of the beam path of the light.

A laser or a laser diode can be used as light source. A collimation along a “fast axis” and a “slow axis” can take place.

The light illuminates a master HOE 92 in order to expose a replicated HOE 96 in this way. A light point generated by the light source 52 can be moved over the carrier material of the HOE 96.

In addition, the system 50 also comprises a positioning module 56. The latter comprises one or more motorized actuators 55 and also at least one optical element 54 (which can be passive or active, i.e. can be settable or fixedly oriented).

The motorized actuators 55 can position at least one optical element 54 in accordance with a plurality of degrees of freedom. It may be possible to implement one or more degrees of freedom of translational movement. Alternatively or additionally, one or more degrees of freedom of rotational movement can be implemented.

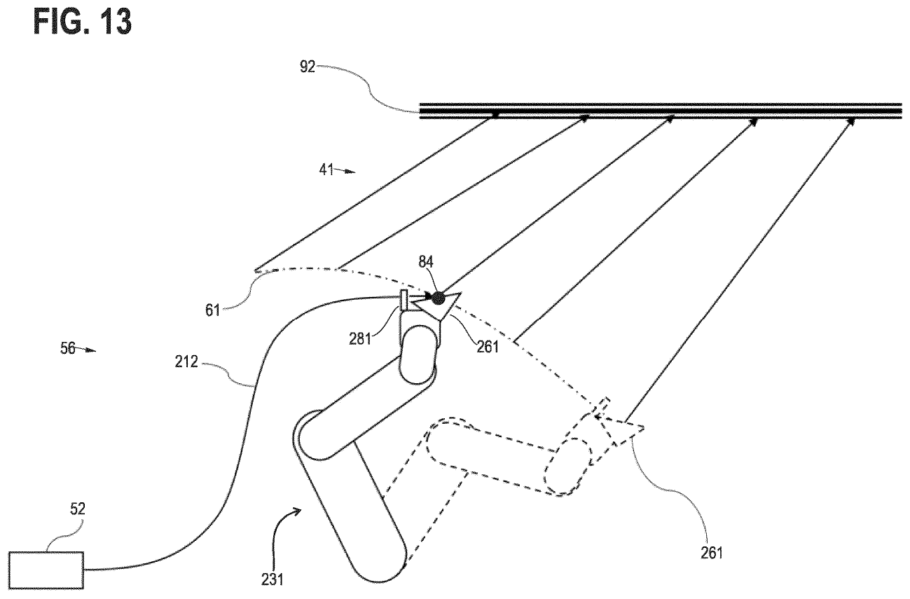

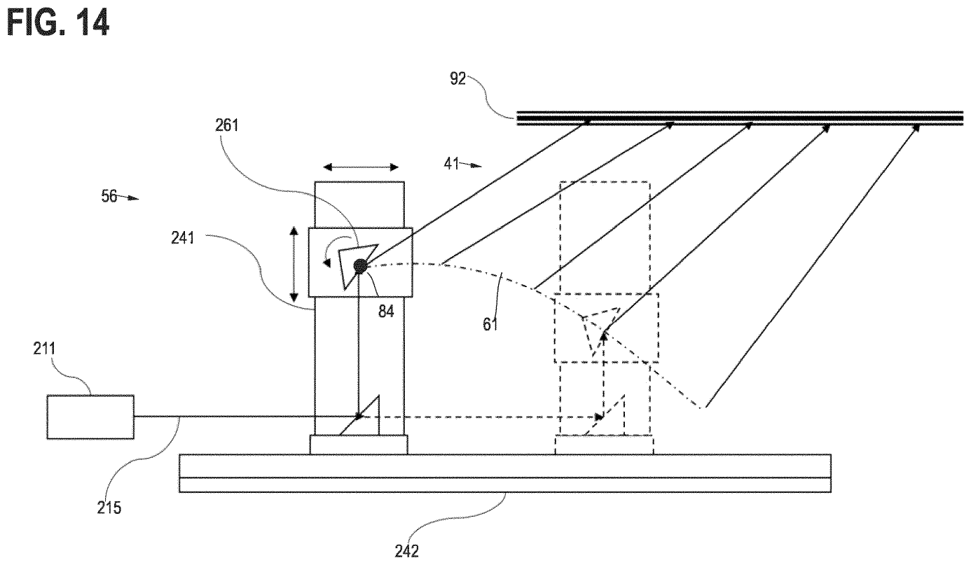

The actuator 55 could be implemented for example by a robotic arm with a plurality of adjustable axes. An implementation by means of a multi-axis optical linear adjustment table would also be conceivable. Corresponding examples will be described later in association with FIG. 13 and FIG. 14.

The actuator 55 can be controlled by the controller 51.

As a general rule, the at least one optical element 54 can be implemented for example by a mirror or a prism. The at least one optical element 54 could alternatively or additionally comprise one or more lens elements.

An at least partly collimated beam can be generated by the at least one optical element 54.

In some examples, it would be conceivable for the at least one optical element to comprise a scanning mirror that can scan the beam path 41. In such a case, the scanning mirror can be controlled by the controller 51. Different scanning patterns can be used. In one example, a Cartesian scanning pattern is used. That means that lines are scanned successively. A spiral scanning pattern could also be used. A plurality of ellipses could be used (elliptic scanning pattern), which e.g. gradually become smaller or larger. Depending on the choice of scanning pattern, for example specific aberrations can be compensated for. By way of example, a spiral scanning pattern or an elliptic scanning pattern could be particularly suitable for correcting spherical aberrations.

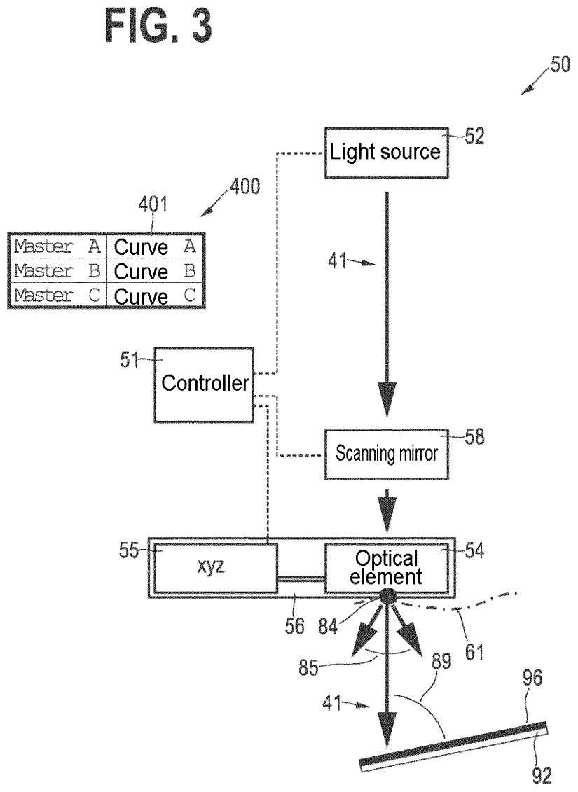

It is not necessary in all scenarios for a scanning mirror-if present at all-to be integrated into the positioning module 56. By way of example, FIG. 3 shows a modification of the system from FIG. 2 in which the scanning mirror 58 is arranged in the beam path 41, but separately from and upstream of the positioning module 56 along the beam path 41 (that is to say offset with respect to the light source 52).

By means of the positioning module 56, it is possible to move a reference point 84, which is arranged along the beam path 41 (here in the optical element 54), on a trajectory 61 (indicated by the dotted-dashed line). The trajectory 61 thus denotes the path along which the reference point 84 of the beam path moves while the master HOE 92 is being replicated. What can be achieved as a result is that the angle of incidence can be varied in a targeted manner as a function of the position of the light point on the master HOE 92.

The trajectory 61 can for example be curved (i.e. in a global coordinate system of the system 50, as shown in FIG. 2). The trajectory 61 can have a component which runs perpendicular to the carrier layers of the master HOE 92 and of the HOE 96. The trajectory 61 can have a component which runs parallel to the carrier layers of the master HOE 92 and of the HOE 96. It is assumed hereinafter that the trajectory 61 is curved; however, it would also be conceivable for the trajectory 61 to be straight rather than curved.

In this case, the controller 51 can be configured to control the positioning module 56 during the exposure process (that is to say while the light source 52 is being controlled in order to emit the light along the beam path 41), with the result that the reference point 84 is moved in relation to the master HOE 92 on the curved trajectory 61.

The controller 51 can also be configured to vary the emergence angle 85 of the light from the reference point 84 during the exposure process. For example, for this purpose, a mirror of the at least one optical element 54 could be tilted in relation to the actuator 55 or a (rigid) mirror oriented fixedly in relation to the actuator 55 could be positioned differently with respect to the light source 52.

The controller 51 is correspondingly configured to vary the angle 89 of incidence of the light on the carrier layer of the master HOE 92 or of the HOE 96 during the exposure process.

By virtue of the movement along the trajectory 61 and/or by virtue of the variation of the emergence angle 85, an angle 89 of incidence of the light on the master HOE 92 is varied as a result.

For the purpose of controlling the positioning module 56 and optionally the scanning mirror 58, the controller 51 can load control data 401 specifying the movement of the actuator 55 and/or optionally of a settable optical element 54, from a corresponding control data lookup table 400. For example, the suitable control data can be selected depending on the master HOE used. That means that different curved trajectories 61 are used in each case for different master HOEs.

The control data 401 could be provided for example by a manufacturer of the master HOE. The control data 401 could be determined for example in connection with box 3005 from FIG. 1.

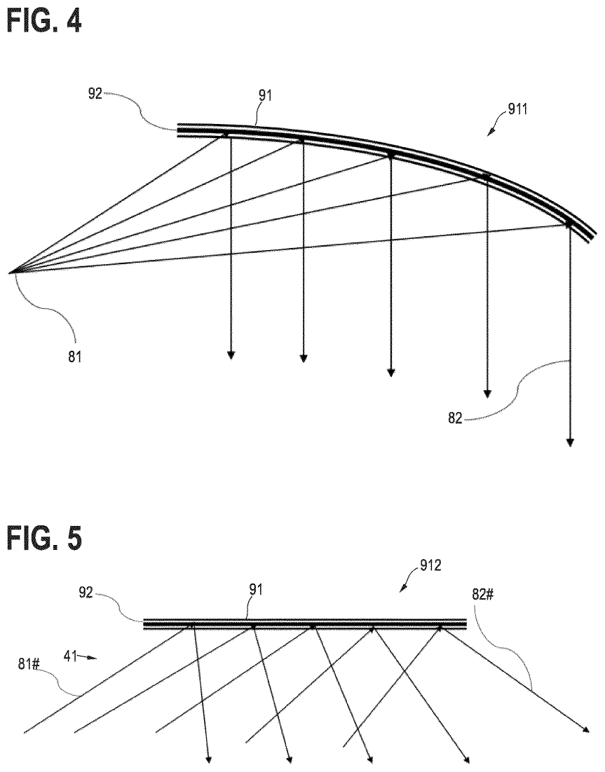

This dependence of the curved trajectories 61 on the master HOE used stems from the fact that, depending on the master HOE 92, different target surface shapes 911 can be used (wherein the exposure process for replication can take place in each case in the same exposure surface shape 912 because this exposure surface shape 912 is dictated by the replication process used). Accordingly, a different compensation has to be effected by the curved trajectory 61. This is explained below in association with FIG. 4 and FIG. 5.

FIG. 4 illustrates aspects in relation to the target surface shape 911. FIG. 4 illustrates the master HOE 92 on the corresponding carrier layer 91, which has the target surface shape 911.

In the example in FIG. 4, the master HOE 92 implements an optical functionality of an off-axis paraboloidal mirror that is illuminated by a point light source. An incident divergent beam 81 is converted to a parallel beam 82. That is just one exemplary optical functionality, and a broad spectrum of different optical functionalities is conceivable in principle.

In any case, the replicated HOE 96 is intended to implement the corresponding optical functionality if the replicated HOE 96 has the same target surface shape 911.

During exposure of the replicated HOE 96 (cf. FIG. 1: box 3010) the replicated HOE 96 and the master HOE 92 (only the master HOE 92 is shown in FIG. 5) have the exposure surface shape 912, however. The latter is shown in FIG. 5.

The transformation between the target surface shape 911 and the exposure surface shape 912 causes a change in the diffraction structure of the master HOE 92; this change in the diffraction structure can be correspondingly translated into a change in the rays of the incident beam 81# and the rays of the reflected beam 82#: These beams 81# and 82# are “drawn” in the drawing plane, just like the diffraction structure.

Various examples are based on the insight that in order to produce the replicated HOE 96 with the use of the exposure surface shape 912, the beam path 41 of the light used for exposure are intended to simulate the rays of the adapted beam 81# (cf. FIG. 5) in order in this way to ensure the optical functionality of the replicated HOE 96 in accordance with FIG. 4 (shown there for the master HOE 92) with the presence of the target surface shape 911.

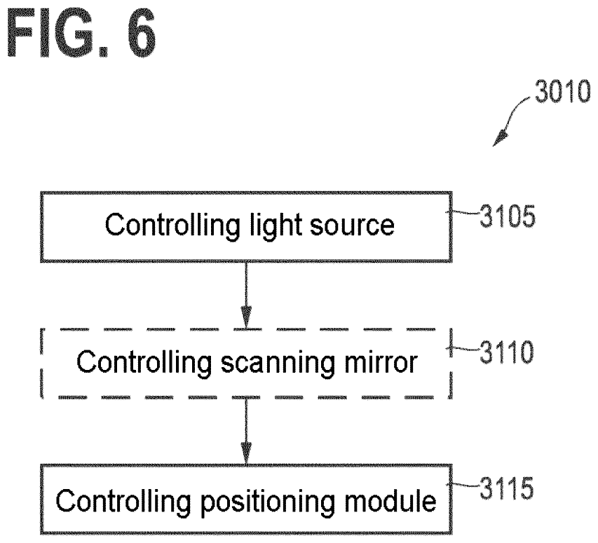

This is made possible by means of a method discussed below in association with FIG. 6.

FIG. 6 illustrates one exemplary method. The method in FIG. 6 serves for producing a replicated HOE. In particular, the method in FIG. 6 concerns the replication process, cf. FIG. 1: box 3010. By way of example, the method from FIG. 6 could be implemented by a controller, for example by the controller 51 of the system 50 from FIG. 2. For example, a corresponding processor could load and execute program code from a memory in order to carry out the method from FIG. 6. By means of the method from FIG. 6, it is possible to move a light point over the carrier layer of a master HOE in order in this way to replicate a diffraction structure of the master HOE into the carrier layer of a HOE. The HOE is thus exposed. By means of the method from FIG. 6, what is achieved in particular is that this exposure takes place sequentially by the movement of a light point over the carrier layer. In this case, the angle of incidence of the light can be varied as a function of the position of the light point on the carrier layer.

In box 3105, a light source, for example a laser, is controlled in order to emit light along a beam path onto a master HOE. For example, the light source could be controlled in such a way that it continuously emits light at a specific light intensity during an exposure process.

Optionally, subsequently in box 3110, a scanning mirror can be controlled in order to scan the light in relation to the master HOE during the exposure process. By way of example, a corresponding scanning mirror 58 was discussed in connection with the system 50 in the example in FIG. 3; it would also be conceivable for the scanning mirror to be part of the positioning module, cf. FIG. 2.

In some examples, no scanning mirror at all is required. Accordingly, box 3110 is optional.

Afterward, in box 3115, the positioning module 56 is controlled in order to move a reference point along the beam path of the light in relation to the master HOE on an e.g. curved trajectory during the exposure process. Aspects in connection with the curved trajectory 61 have been discussed above in association with FIG. 2 and FIG. 3.

Optionally, it would also be conceivable for the positioning module also to be controlled in box 3115 in order to change the emergence angle of the beam path at the reference point during movement of the reference point along the curved trajectory in relation to the master HOE. It is thus possible to effect a separate movement for changing the emergence angle and for movement along the curved trajectory.

By means of such techniques, it is possible to vary the angle of incidence of the light on the master HOE 92. For example, a flatbed replication process or a roll-to-roll replication process can benefit from this.

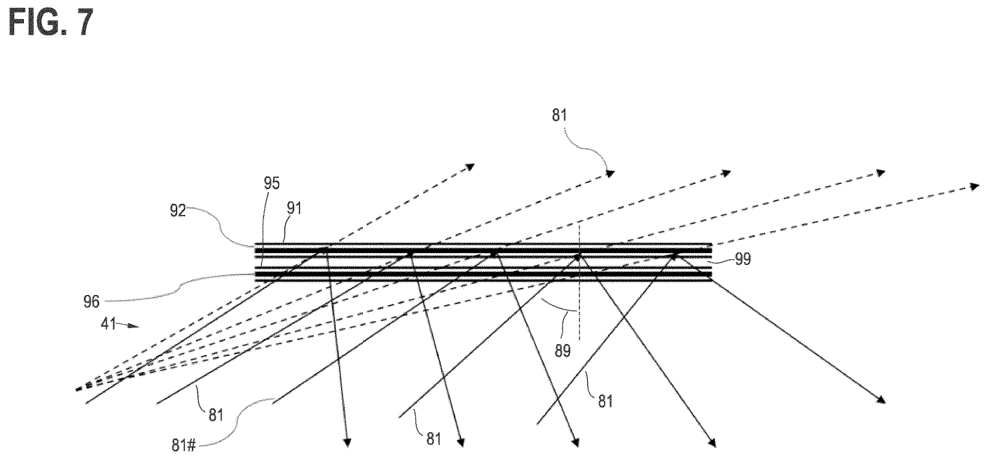

FIG. 7 illustrates aspects in connection with a flatbed replication process for replicating the master HOE 92, for exposing the replicated HOE 96. FIG. 7 illustrates that the carrier layer 91 of the master HOE 92 extends parallel to the carrier layer 95 of the replicated HOE 96 during the exposure of the replicated HOE 96. For this purpose, a corresponding fixing element is used, e.g. rolls for a roll-to-roll replication process or—as in the example in FIG. 7—one or more fixing frames 99 for a flatbed replication process. For the exposure of the replicated HOE 96, the master HOE 92 is illuminated with light along the beams 81#; it is evident from FIG. 7 that the angle 89 of incidence of these beams 81# varies as a function of the position of the corresponding light point on the master HOE 92, which is achieved by using the curved trajectory 61 of the reference point 84 along the beam path 41 and optionally by changing the emergence angle of the light from the reference point 84 (cf. FIG. 2 and FIG. 3). If the replicated HOE 96 is then in the application and has the target surface shape 911, it is again possible to effect an illumination with other beams (illustrated by the dashed arrows in FIG. 7), as already described above in the joint consideration of FIGS. 4 and 5.

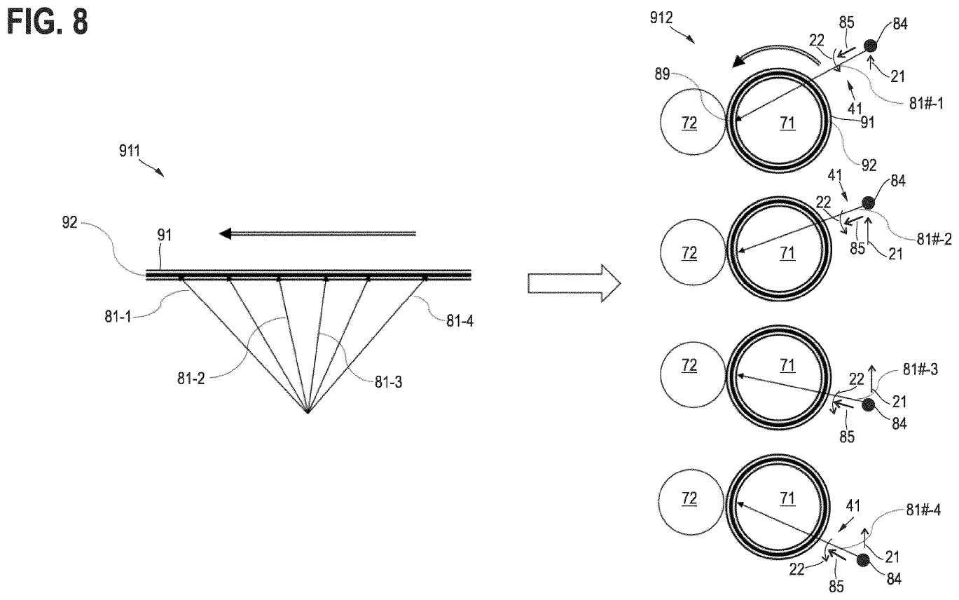

FIG. 8 illustrates aspects in connection with a roll-to-roll replication process for replicating the master HOE 92, that is to say for exposing the replicated HOE 96. FIG. 8 shows on the left a section through the master HOE 92 in the event of the latter having the target surface shape 911, i.e. when it is being produced (cf. box 3005 in FIG. 1). In addition, it shows the corresponding rays 81-1-81-4 of a beam which is used for the exposure used later, during application of the replicated HOE 96, for the illumination of the replicated HOE 96.

In the roll-to-roll replication process (cf. box 3010 in FIG. 1), the master HOE 92 is applied on a roll 71 as fixing element and the corresponding rays 81#-1-81#-4 of the beam path 41 of the light which are used to illuminate the master HOE 92 are attained with increasing rotation of the roll 71 by a movement 21 of the reference point 84 and a correspondingly changed emergence angle 85 of the light from the reference point 84 (e.g. attained by tilting 22 a corresponding mirror arranged at the reference point 84). As a result, therefore, during the exposure process of the replicated HOE (which is applied on a further roll 72 and is not shown in FIG. 8 for reasons of clarity), the curvature of the carrier material 91 of the master HOE 92 is compensated for by the curved trajectory.

Techniques in connection with the movement of the reference point 84 have been explained above. The way in which the emergence angle 85 can be changed has additionally been explained. It is optionally possible to synchronize the movement of the reference point 84 along the curved trajectory 61 with a scanning of the light beam 41 (cf. FIG. 3: scanning mirror 58). In contrast to a change in the emergence angle 85, as discussed above, the scanning of the light beam 41 can be implemented by a periodic scanning movement.

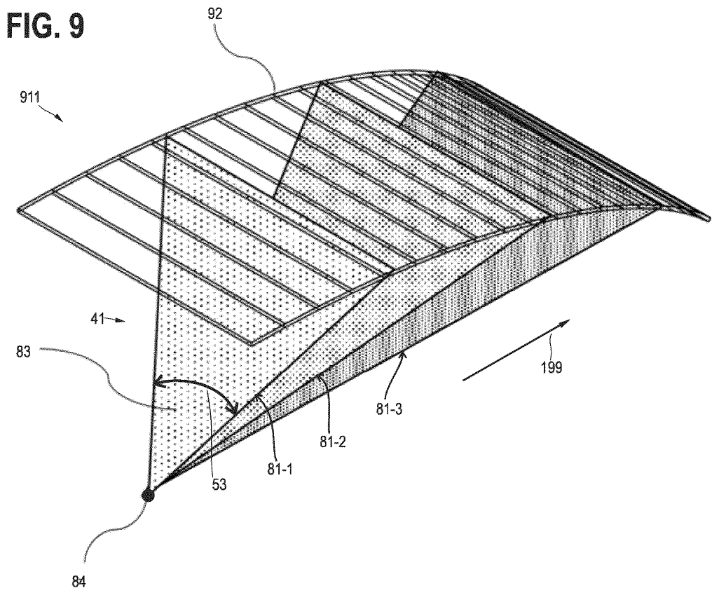

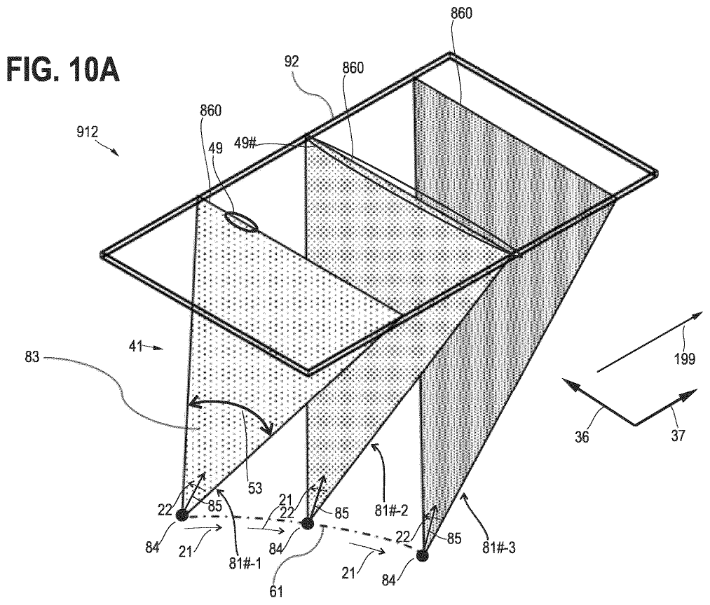

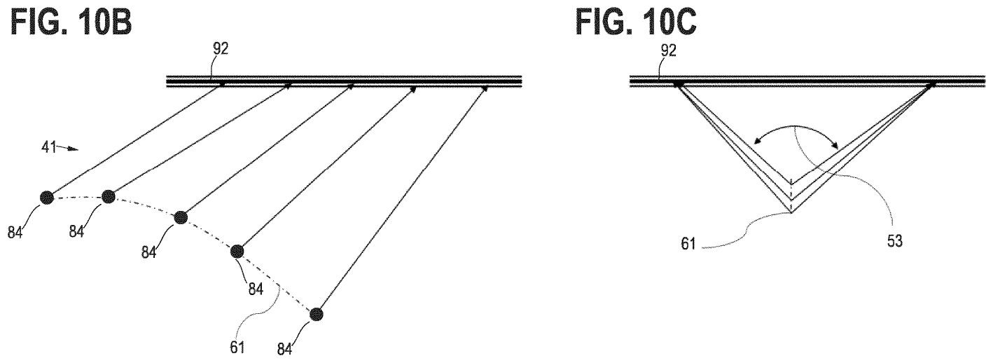

For example, the reference point 84 could mark a midpoint of the scanning movement 53. Aspects in connection with the scanning are illustrated below in association with FIG. 9 and FIG. 10A.

FIG. 9 shows a master HOE 92, which implements the optical functionality of an off-axis parabolic mirror by way of example. FIG. 9 shows the master HOE 92 in the target surface shape 911; FIG. 10A shows the same master HOE 92 in the exposure surface shape 912. It is evident from FIG. 9 that the master HOE 92 in the target surface shape 911 has a one-dimensional curvature along an axis 199 of curvature.

That means that it is possible to mediate between the target surface shape 911 and the exposure surface shape 912 by way of a one-dimensional curvature operation along the axis 199 of curvature (a curvature perpendicular to the axis 199 of curvature is not changed). The same correspondingly applies (in inverse form) to the example in FIG. 8. Put generally, a transition between a one-dimensional curvature of the carrier layer 91 of the master HOE and a planar configuration of the carrier layer 91 of the master HOE 92 thus takes place. That can be referred to as “development” of the area describing the carrier layer.

The scanning direction 36 of the scanning movement 53 of a scanned light point 49 on the master HOE 92 by means of the scanning mirror is oriented perpendicular to the axis 199 of curvature, cf. FIG. 10A. This is due to the fact that no displacement of the origin of the scanning movement 53 needs to occur perpendicular to the axis 199 of curvature because there is no transformation of the curvature of the corresponding surface in this direction 36.

The example in FIG. 10A thus corresponds to a line scanner (i.e. a Cartesian scanning pattern in which a plurality of one-dimensional lines 860 are scanned).

The movement of the reference point 84 along the curved trajectory 61 takes place in a manner superimposed with the scanning movement 53 along the scanning direction 36. This shifts the light point 49 along the direction 37. The corresponding movement 21 has a component along an axis 37 that is oriented perpendicular to the scanning direction 36 (and thus parallel to the axis 199 of curvature) along the direction 37.

FIG. 10A also shows the (non-scanned) change in the emergence angle 85 by way of a corresponding control of the positioning module. In some examples, a two-dimensional scanning mirror could be used to implement both scanning (i.e. a periodic movement around a scan mid-point) along the scanning direction 36 and also the non-scanned change in the emergence angle 85, for example by way of a corresponding tilting 22 at the reference point 84. A corresponding scenario has been discussed in association with FIG. 2; the scanning mirror can then be arranged at the reference point 84.

In the example in FIG. 10A, the scanning could be effected with a fixed scanning frequency of a fixed scanning amplitude, with the result that the entire region between the two edges of the master HOE 92 is swept over by the light point 49. In such an example, in particular a resonantly driven scanning mirror could be used.

Not all examples require the implementation of the scanning movement 53. For example, at least one optical element could also be arranged at the reference point 84, which optical element causes the light point 49# of the light on the master HOE 92 to be expanded along the direction 36 (compare light point 49 with light point 49#). The otherwise scanned lines are then exposed in an integrated manner.

FIG. 10B and FIG. 10C are side views from mutually perpendicularly oriented perspectives for the scenario in FIG. 10A.

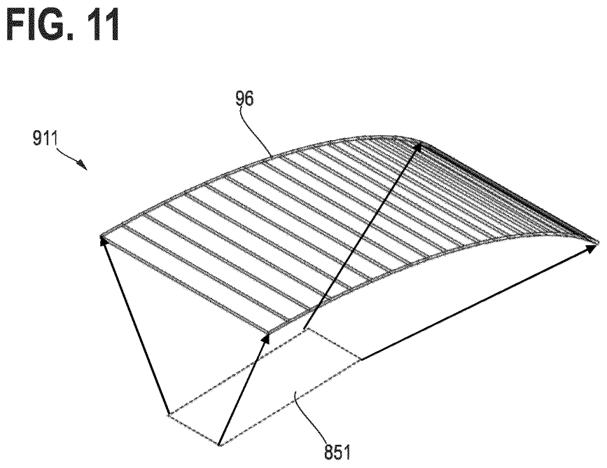

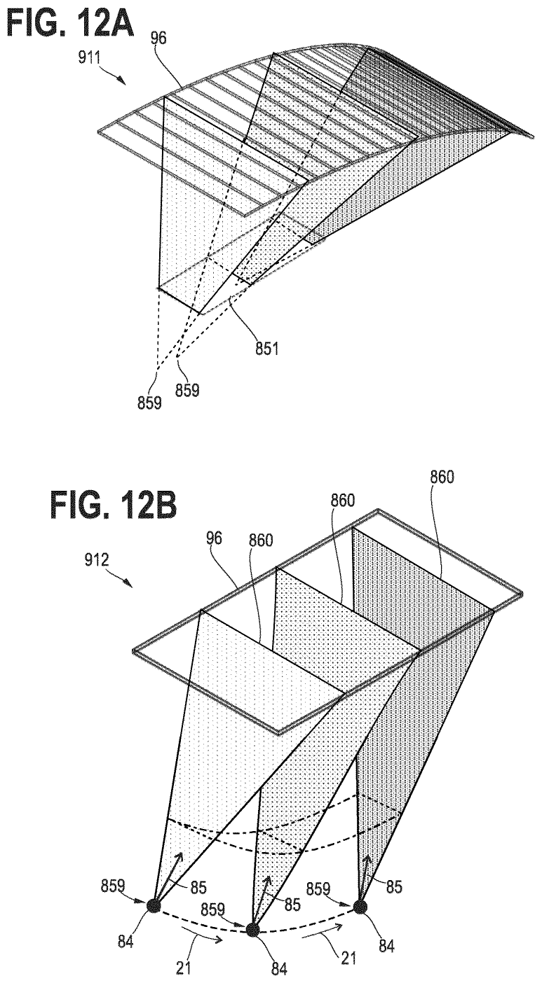

In the example in FIGS. 9, 10A, 10B and 10C, a point light source for illuminating the HOE during the replication of the hologram is assumed. However, it is likewise possible to replicate HOEs which are illuminated by areal light sources or area emitters for the reconstruction of the hologram. That could be, in the application, e.g. organic light emitting diodes (OLEDs) or light guide exit areas or array arrangements such as e.g. LED panels. FIG. 11 shows the replicated HOE 96 in the target surface shape, i.e. after system integration. This corresponds, in principle, to the scenario in FIG. 9 (which shows the master HOE 92); in FIG. 11, use is made of an extensive light source 851 for illuminating the HOE 96 for the reconstruction of the hologram. As evident in FIG. 12A and FIG. 12B, the extensive light source 851 (or generally areal light sources) can also be decomposed into scan lines 860 of a Cartesian scanning pattern.

FIG. 12A here first illustrates how the divergent beam path of the light from the light source 851 can in each case be locally translated into a position of a point light source. This is done by lengthening the beams away from the various positions of light source 851 as far as corresponding intersection points 859 (these intersection points then correspond to the arrangement of the reference point or the point light source during replication). The reference point 84 is then arranged there during the exposure. This is done firstly in the target surface shape (FIG. 12A) and is then calculated for the exposure surface shape 912 (FIG. 12B). As a result of the development of the area shown in FIG. 12B, the path of the intersection points 859 (or the reference point 84) changes, with the result that the trajectory 61 is obtained for the reference point 84.

That means, in other words, that reference points 84 are calculated which represent the lengthening of the spanned scan line 860 into an intersection point 859. The areal light source 851 can thus likewise be represented by a moved reference point.

Such techniques can be taken into account in the calculation of the control data 401. When calculating the control data, it is thus possible to take account of the geometry of the light source 851 which is used for reconstructing the hologram during illumination of the HOE. In particular, an areal extent of the light source 851 can be taken into account.

These techniques make it possible to use a point light source, for example at the reference point 84. Alternatively, the areal light source 851 during the illumination of the HOE for reconstructing the hologram could also be attained by the use of suitable optics for the light source during the exposure for the replication of the master HOE. By way of example, suitable optics enabling an areal exposure could be arranged at the reference point 84.

FIG. 13 shows one exemplary implementation of the positioning module 56 for the scenario in FIGS. 10-12 (where the positioning module 56 from the example in FIG. 13 can also be used for other scenarios). The positioning module 56 comprises a robotic arm 231, which implements the actuator 55 (cf. FIG. 2). An optical fiber 212 guides the light from the laser 52 to the moving end of the robotic arm 231. There, the light is coupled out by an output coupling unit 281, which can comprise for example a corresponding lens element (GRIN lens element), etc. The output coupling unit 281 can be designed to maintain polarization. In addition, a two-dimensional galvo scanner 261 is arranged at the moving end of the robotic arm 231; as shown in FIG. 13, this galvo scanner 261 implements both the tilting 22 for the non-scanning change of the emergence angle 85 at which the light leaves the reference point 84; and also the scanning movement 53 of the light beam 41 (which in FIG. 13 would be oriented perpendicular to the plane of the drawing).

Other techniques can also be used instead of a robotic arm 231 for the implementation of the positioning module 56. One example is shown in FIG. 14.

FIG. 14 shows one exemplary implementation of the positioning module 56 for the scenario in FIGS. 10-12 (where the positioning module 56 from the example in FIG. 14 can also be used for other scenarios). The positioning module 56 comprises a linear adjustment table 241, 242. A three-axis linear adjustment table moves the reference point 84 on the curved trajectory 61. A two-dimensional scanning mirror 261 is again provided. A rotary table and a one-dimensional scanning mirror could also be used.

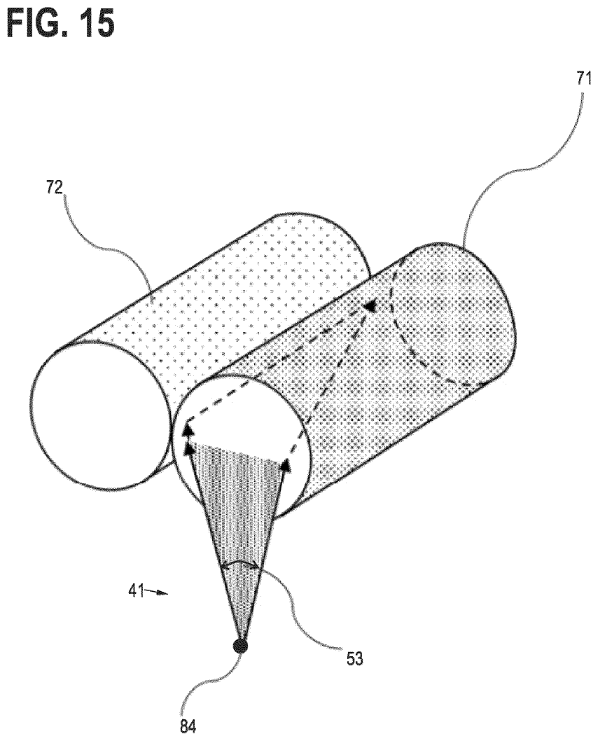

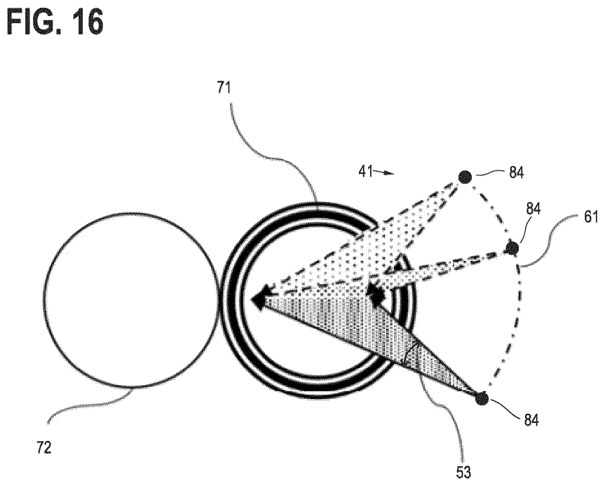

FIG. 15 shows the roll-to-roll replication of a master HOE 92 which is intended to be illuminated in the target surface shape 911 by a point light source. The replication can only ever take place along the linear contact area between both rolls 71, 72. The exposure can involve e.g. lateral incoupling into the end face or illumination through the roll (glass roll). Since the exposure direction changes locally depending on the illumination situation (such as point light source), the shape of the scan line must also be varied during the rotation of the rolls. This can likewise be done by the combination of a movement of a scanning mirror and the synchronized change of the scanning movement of the scanning mirror (1-D or 2-D), cf. FIG. 16.

Various aspects have been disclosed above in connection with the production of a HOE which enables a flexible choice of the surface shape when replicating a master HOE. However, the techniques described herein do not just enable the flexible choice of the surface shape when replicating the master HOE. The disclosed techniques of flexibly moving the reference point along differently shaped trajectories make it possible to generate wavefronts for the replication process with a multiplicity of degrees of freedom. In this way, it is possible to take account of various influences during manufacturing (over and above specific surface shapes during replication). By way of example—as an alternative or in addition to a compensation of different surface shapes when replicating the master HOE and when generating the master HOE or during system integration of the replicated HOE—aberrations can be flexibly compensated for. This will be explained in greater detail with reference to the following figures.

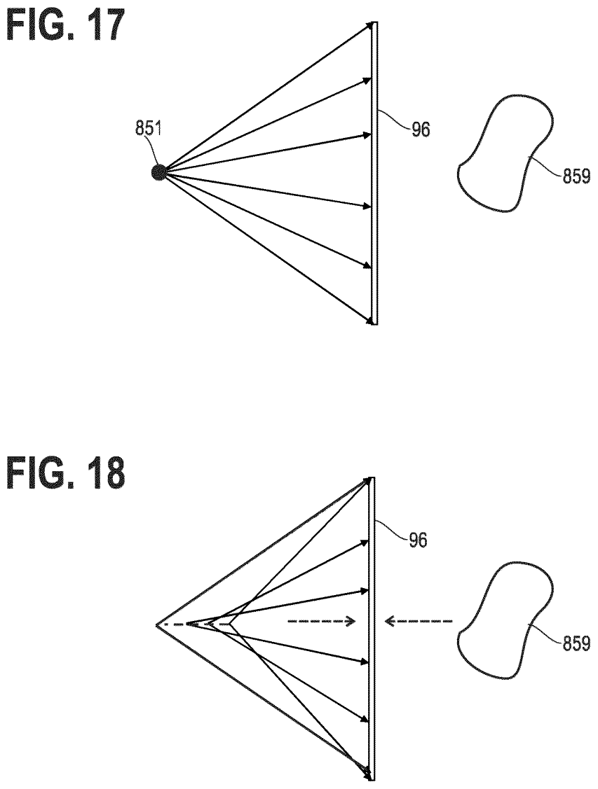

FIG. 17 shows a HOE 96 (for example a volume HOE) with a point light source 851. The illumination by the point light source reconstructs a hologram 859. Aberrations may arise on account of imperfections; that is shown for the example of a spherical aberration in FIG. 18. By comparison with the ideal hologram, the focus point of the reconstruction wave shifts depending on the location of the HOE 96.

The spherical aberration is caused by shrinkage of the carrier layer of the HOE 96; the shrinkage occurs perpendicular to the substrate (i.e. along the plane normals; that is shown by the dashed arrows in FIG. 18).

The spherical aberration then occurs because the shrinkage has a varying effect on the different (optical) deflection angles. One example: A volume grating that deflects a beam by 30° is embossed in the polymer. Elsewhere there is a deflection by 50°. The structure which causes 50° deflection is then tilted by the “anisotropic” shrinkage to a greater extent than the structure with the 30°. As a result, e.g. a lens element function (radially different deflection angles) does not change uniformly over the carrier material layer, but rather locally differently—and the spherical aberration arises.

Such shrinkage or contraction of the carrier layer occurs for example if the carrier layer of the HOE 96 is integrated into a system and in the course of this is clamped into a frame or carrier or is adhesively bonded thereto, for example. Aberrations or imaging aberrations can alternatively or additionally occur during the replication process when the HOE is exposed. By way of example, such aberrations can occur on account of the fixing of the carrier layer of the HOE along the carrier layer of the master HOE. Aberrations can alternatively or additionally occur if the carrier layer of the HOE is integrated in a master plate with the master HOE. Alternatively or additionally, aberrations can also occur during the illumination process after system integration, i.e. when the HOE is being illuminated in order to reconstruct the hologram 859. The carrier layer of the HOE is integrated into a carrier in such a case. By way of example, material expansion can occur on account of temperature fluctuations.

In order to reconstruct the hologram 859 without corruption in the case of such a shrunk carrier layer of the HOE 96, wavefronts are generated in accordance with the spatially variable light source 851 (dashed line) shown in accordance with FIG. 18.

Put more generally: An existing or anticipated aberration can be compensated for during the replication process (in addition or as an alternative to the compensation of different surface shapes and/or different illumination geometries or emitter geometries). This can be done as shown in FIG. 19 for the example of the spherical aberration. Since a spherical aberration is a virtually rotationally symmetrical effect, e.g. using a 2-D scanning head (2-D tiltable scanning mirror) it is possible to draw an elliptic or circular (“donut”) scan line on the carrier layer of the master HOE or the carrier layer of the HOE. A spiral or elliptic scanning pattern could be used. FIG. 19 shows how the light point 49 for the exposure is guided from the outside inward to a center 96z of the HOE 96. Therefore, the scanning process does not scan a plurality of straight lines (as in the case of a Cartesian scanning pattern), but rather a circle decreasing in size (the “scanning circle” becomes smaller and smaller in its radius and moves from the outside inward). Synchronously therewith, the reference point 84 is moved away from the HOE 96 or the master HOE 92 (the straight trajectory 61 is shown) in order thus to realize a different focus point for each radius of the scanning circle. The master HOE 92 is thus scanned with a cone rather than a plane. The movement of the reference point 84 corresponds to a change in location of the cone vertices.

Analogously thereto, other aberrations can be generated (and thus proactively compensated for) by choosing a scanning pattern which matches the “symmetry” of the aberration. These can be described e.g. as Zernike polynomials. Such a combination of scanning pattern and movement of the reference point 84 on arbitrary trajectories 61 allows virtually arbitrary wavefronts to be generated for the replication.

Techniques such as have been described in association with FIG. 17, FIG. 18 and FIG. 19 can be combined with techniques such as have been described above in association with the other figures, for example in association with FIG. 12B or FIG. 10A. That means, in other words, that the compensation of aberrations can be used in addition to a compensation of different surface shapes of the master HOE. By way of example, it is possible to superimpose the different trajectories 61 and emergence angles 85 for compensation of different surface shapes 911, 912 and for the correction of the aberration.

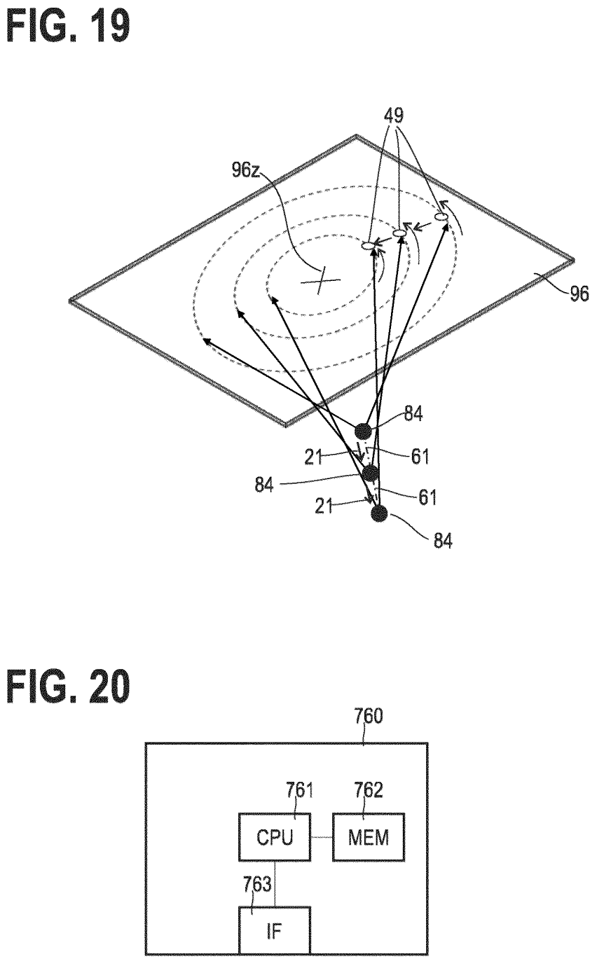

FIG. 20 schematically illustrates a data processing unit 760. The data processing unit 760 could be implemented by a computer, for example. The data processing unit 760 could implement the controller 51, for example. The data processing unit 760 comprises a processor 761 configured to load program code from a memory 762. The processor is further configured to execute the program code. When the processor 761 executes the program code, this has the effect that the processor performs techniques such as are described herein, for example: calculating control data for a positioning module of an exposure system, for example for the positioning module 56; controlling such an exposure module; controlling the light source; etc. The processor could carry out e.g. at least parts of the method from FIG. 6. Control data can be output e.g. via a communication interface 763. Control commands to elements of an exposure system can also be output via the communication interface 763.

In summary, the following examples, in particular, have been described:

EXAMPLE 1. A device (50) for producing a holographic optical element, HOE, (96), wherein the device (50) comprises:
at least one fixing element (71, 72, 99) on which a carrier layer (91) of a master HOE (92) and a carrier layer (95) of the HOE (96) can be arranged during an exposure process, with the result that these extend at least locally along one another,
a radiation source (52) configured to emit light (41) onto the master HOE (92) during the exposure process, with the result that the HOE (96) is exposed, and
a positioning module (56) configured to move a beam path of the light during the exposure process relatively in relation to the carrier layer (91) of the master HOE (92) and the carrier layer (95) of the HOE (96).

EXAMPLE 2. The device according to EXAMPLE 1,
wherein the positioning module comprises at least one out of a robotic arm and a multi-axis optical linear adjustment table (241, 242).

EXAMPLE 3. The device according to EXAMPLE 1 or 2,
wherein the at least one fixing element comprises a first roll for the carrier layer of the master HOE,
wherein the at least one fixing element comprises a second roll for the carrier layer of the HOE.

EXAMPLE 4. The device according to EXAMPLE 1 or 2,
wherein the at least one fixing element comprises at least one fixing frame for a flatbed replication process.

EXAMPLE 5. The device according to any of the preceding EXAMPLES, furthermore comprising:
a controller (51) configured to control the positioning module on the basis of control data.

EXAMPLE 6. The device according to EXAMPLE 5,
wherein the controller is configured to control the positioning module in order to move a light point of the light over the carrier layer of the HOE during the exposure process, with the result that the HOE is exposed at different positions of the light point on the carrier layer at different angles of incidence.

EXAMPLE 7. The device according to EXAMPLE 5 or 6,
wherein the controller is configured to control the positioning module in order to move a reference point, which is arranged along the beam path of the light, in relation to the master HOE on
a trajectory during the exposure process.

EXAMPLE 8. The device according to EXAMPLE 7,
wherein the trajectory is curved.

EXAMPLE 9. The device according to EXAMPLE 7 or 8,
wherein the trajectory has at least one out of a component perpendicular to the carrier layer of the HOE and a component parallel to the carrier layer of the HOE.

EXAMPLE 10. The device according to any of EXAMPLES 7 to 9,
wherein the controller is configured to control the positioning module in order to change an emergence angle (85) of the beam path (41) at the reference point in relation to the master HOE (92) during the exposure process.

EXAMPLE 11. The device according to any of EXAMPLES 5 to 10,
wherein the control data (401) specify at least one out of a trajectory (61) for a reference point along the beam path, an emergence angle (85) of the beam path (41) at the reference point in relation to the master HOE and an angle (89) of incidence of the light on the master HOE.

EXAMPLE 12. The device according to any of the preceding EXAMPLES, furthermore comprising:
a scanning mirror (54, 58) configured to scan the light in relation to the master HOE during the exposure process.

EXAMPLE 13. The device according to EXAMPLE 12,
wherein the positioning module comprises the scanning mirror.

EXAMPLE 14. The device according to EXAMPLE 12 or 13, and according to any of EXAMPLES 7 to 11,
wherein the scanning mirror is arranged at the reference point.

EXAMPLE 15. The device according to EXAMPLE 14,
wherein the controller is configured to control the scanning mirror (54) in order, in a manner superimposed with the scanning, to tilt the emergence angle (85) of the beam path at the reference point (84) in relation to the master HOE (92).

EXAMPLE 16. The device according to any of EXAMPLES 12 to 15,
wherein the controller is configured to control the scanning mirror in order to scan the light with a scanning pattern selected from the following group: Cartesian scanning pattern; spiral scanning pattern; circular scanning pattern; elliptic scanning pattern; line scanning; one-dimensional scanning; two-dimensional scanning.

EXAMPLE 17. The device according to any of EXAMPLES 12 to 17,
wherein the scanning mirror (54) is a two-dimensionally tiltable scanning mirror.

EXAMPLE 18. The device according to any of the preceding EXAMPLES, furthermore comprising:
at least one optical element (54) which is arranged along a beam path of the light and which has the effect that a light point (49#) of the light on the master HOE (92) is expanded along at least one axis (36).

EXAMPLE 19. The device according to EXAMPLE 18, and according to any of EXAMPLES 7 to 11,
wherein the at least one optical element is arranged at the reference point.

EXAMPLE 20. The device according to any of the preceding EXAMPLES,
wherein the radiation source comprises a laser.

EXAMPLE 21. A data processing unit (760) comprising at least one processor (761) and a memory (762), wherein the at least one processor (761) is configured to load and to execute program code from the memory, wherein the at least one processor is configured, on the basis of the program code, to calculate control data for a control of a device for producing a holographic optical element.

EXAMPLE 22. The data processing unit according to EXAMPLE 21, wherein the control data (401) specify at least one out of a trajectory (61) for a reference point along the beam path, an emergence angle (85) of the beam path (41) at the reference point in relation to the master HOE and an angle (89) of incidence of the light on the master HOE.

EXAMPLE 23. The data processing unit according to EXAMPLE 21 or 22, wherein the at least one processor, on the basis of the program code, furthermore calculates the control data on the basis of a first surface shape (911) of the carrier material (91) of the master HOE (92) during a further exposure process for exposing the master HOE (92), and on the basis of a second surface shape (912) of the carrier material (91) of the master HOE (92) during the exposure process, and further on the basis of an angle (89) of incidence of light as a function of the location on the master HOE (92) during the further exposure process.

EXAMPLE 24. The data processing unit according to any of EXAMPLES 21 to 23, wherein the at least one processor, on the basis of the program code, furthermore calculates the control data (401) on the basis of a geometry of a light source (851) which is used for reconstructing a hologram by illumination of the HOE.

EXAMPLE 25. The data processing unit according to any of EXAMPLES 21 to 24, wherein the at least one processor, on the basis of the program code, furthermore calculates the control data (401) on the basis of a predefined aberration.

EXAMPLE 26. The data processing unit according to any of EXAMPLES 21 to 25, wherein the at least one processor, on the basis of the program code, is configured to calculate the control data for the control of the device according to any of EXAMPLES 1 to 20.

Besides such examples in connection with devices and data processing units, the following examples in connection with methods have also been described. The examples reproduced above can be combined with the examples reproduced below in order to form further examples.

EXAMPLE 1. A method for producing a holographic optical element, HOE, (96) by replicating (3010) a master HOE (92) in the context of an exposure process, wherein a carrier layer (91) of the master HOE (92) is arranged along a carrier layer (95) of the HOE (96) during the exposure process,
the method comprising the following steps:
controlling (3105) a radiation source (52) in order to emit light onto the master HOE (92) during the exposure process, with the result that the HOE (96) is exposed, and
controlling (3115) a positioning module (56) in order to move (21) a reference point (84), which is arranged along a beam path (41) of the light, in relation to the master HOE (92) on a curved trajectory (61) during the exposure process.

EXAMPLE 2. The method according to EXAMPLE 1,
wherein the positioning module (56) is controlled in order to change an emergence angle (85) of the beam path (41) at the reference point in relation to the master HOE (92) during the exposure process.

EXAMPLE 3. The method according to EXAMPLE 1 or 2, wherein the method furthermore comprises:
controlling a scanning mirror (54, 58) in order to scan (53) the light in relation to the master HOE during the exposure process.

EXAMPLE 4. The method according to EXAMPLE 3,
wherein a scanning direction (36) during the scanning of a light point (49) of the light on the master HOE (92) during the exposure process has a component which is orthogonal to a movement direction (37) of the light point (49) of the light on the master HOE (92) which is caused by the movement of the reference point (84) along the curved trajectory (61).

EXAMPLE 5. The method according to EXAMPLE 3 or 4,
wherein the scanning of the light during the exposure process takes place with a fixed scanning frequency and optionally a fixed scanning amplitude.

EXAMPLE 6. The method according to any of EXAMPLES 3 to 5,
wherein the scanning mirror (54) is arranged at the reference point (84),
wherein the beam path (41) of the light is optionally focused at the reference point (84).

EXAMPLE 7. The method according to EXAMPLE 2, and according to any of EXAMPLES 3 to 6,
wherein the scanning mirror (54) is a two-dimensionally tiltable scanning mirror of the positioning module,
wherein the scanning mirror (54) is controlled in order, in a manner superimposed with the scanning, to tilt the emergence angle (85) of the beam path at the reference point (84) in relation to the master HOE (92).

EXAMPLE 8. The method according to any of EXAMPLES 2 to 7,
wherein the scanning of the light takes place with a scanning pattern selected from the following group: Cartesian scanning pattern; spiral scanning pattern; circular scanning pattern; elliptic scanning pattern; line scanning; one-dimensional scanning; two-dimensional scanning.

EXAMPLE 9. The method according to any of the preceding EXAMPLES, wherein the method furthermore comprises:
producing (3005) the master HOE (92) in a further exposure process,
wherein the carrier layer (91) of the master HOE (92) during the further exposure process has a first surface shape (911), which is different than a second surface shape (912) of the carrier layer
during the exposure process.

EXAMPLE 10. The method according to EXAMPLE 9,
wherein one (911, 912) out of the first surface shape and the second surface shape corresponds to a one-dimensional curvature of the carrier layer (91) of the master HOE (92),
wherein the other (912, 911) out of the first surface shape and the second surface shape corresponds to a planar embodiment of the carrier layer (91) of the master HOE (92).

EXAMPLE 11. The method according to EXAMPLE 4 and according to EXAMPLE 10, wherein the scanning direction of the scanning by means of the scanning mirror (54, 58) runs perpendicular to the axis (199) of the one-dimensional curvature.

EXAMPLE 12. The method according to any of the preceding EXAMPLES, wherein at least one optical element (54) is arranged at the reference point (84), having the effect that a light point (49#) of the light on the master HOE (92) is expanded along at least one axis (36).

EXAMPLE 13. The method according to any of the preceding EXAMPLES, wherein the positioning module (56) comprises a robotic arm (231) with a plurality of adjustable axes.

EXAMPLE 14. The method according to any of the preceding EXAMPLES, wherein the positioning module (56) comprises a multi-axis optical linear adjustment table (241, 242).

EXAMPLE 15. The method according to any of the preceding EXAMPLES, wherein the positioning module is controlled on the basis of control data (401) specifying the curved trajectory (61) and optionally an emergence angle (85) of the beam path (41) at the reference point in relation to the master HOE.

EXAMPLE 16. The method according to EXAMPLE 14,
wherein the control data (401) specify an angle (89) of incidence of the light on the master HOE.

EXAMPLE 17. The method according to EXAMPLE 16, wherein the method furthermore comprises:
calculating the control data (401) on the basis of a first surface shape (911) of the carrier material (91) of the master HOE (92) during a further exposure process for exposing the master HOE (92), and on the basis of a second surface shape (912) of the carrier material (91) of the master HOE (92) during the exposure process, and further on the basis of an angle (89) of incidence of light as a function of the location on the master HOE (92) during the further exposure process.

EXAMPLE 18. The method according to EXAMPLE 16 or 17, wherein the method furthermore comprises:
calculating the control data (401) on the basis of a geometry of a light source (851) which is used for reconstructing a hologram by illumination of the HOE.

EXAMPLE 19. The method according to any of EXAMPLES 16 to 18, wherein the method furthermore comprises:
calculating the control data (401) on the basis of a predefined aberration.

EXAMPLE 20. The method according to any of EXAMPLES 15 to 19, wherein the method furthermore comprises:
depending on the master HOE (92): selecting the control data (401) from a control data lookup table (400) comprising a multiplicity of candidate control data associated with different master HOEs.

EXAMPLE 21. The method according to any of the preceding EXAMPLES, wherein the curved trajectory (61) compensates for a curvature of the carrier material (91) of the master HOE (92) during the exposure process.

EXAMPLE 22. The method according to any of the preceding EXAMPLES,
wherein the carrier layer (95) of the HOE (96) has a second surface shape (912) during the exposure process,
wherein the method furthermore comprises:
after the exposure process: fixing (3015) the carrier layer of the HOE in a first surface shape (911), which is different than the second surface shape (912).

EXAMPLE 23. A method for producing a holographic optical element, HOE, (96) by replicating (3010) a master HOE (92) in the context of an exposure process, wherein a carrier layer (91) of the master HOE (92) is arranged along a carrier layer (95) of the HOE (96) during the exposure process,
the method comprising the following steps:
controlling (3105) a radiation source (52) in order to emit light onto the master HOE (92) during the exposure process, with the result that the HOE (96) is exposed, and
controlling (3115) a positioning module (56) in order to move a light point of the light over the carrier layer of the HOE during the exposure process and in order to expose the HOE at different positions of the light point on the carrier layer at different angles of incidence.

EXAMPLE 24. The method according to EXAMPLE 23,
wherein the positioning module is controlled in order to move (21) a reference point (84), which is arranged along a beam path (41) of the light, in relation to the master HOE (92) on a trajectory (61) during the exposure process.

EXAMPLE 25. The method according to EXAMPLE 24,
wherein the trajectory is curved in a global coordinate system.

EXAMPLE 26. The method according to EXAMPLE 24 or 25,
wherein the trajectory has at least one out of a component perpendicular to the carrier layer of the HOE and a component parallel to the carrier layer of the HOE.

EXAMPLE 27. The method according to any of EXAMPLES 24 to 26,
wherein the positioning module (56) is controlled in order to change an emergence angle (85) of the beam path (41) at the reference point in relation to the master HOE (92) during the exposure process.

EXAMPLE 28. The method according to any of EXAMPLES 23 to 27, wherein the method furthermore comprises:
controlling a scanning mirror (54, 58) in order to scan (53) the light in relation to the master HOE during the exposure process.

EXAMPLE 29. The method according to EXAMPLE 28,
wherein a scanning direction (36) during the scanning of a light point (49) of the light on the master HOE (92) during the exposure process has a component which is orthogonal to a movement direction (37) of the light point (49) of the light on the master HOE (92) which is caused by the movement of the reference point (84) along the curved trajectory (61).

EXAMPLE 30. The method according to EXAMPLE 28 or 29,
wherein the scanning of the light during the exposure process takes place with a fixed scanning frequency and optionally a fixed scanning amplitude.

EXAMPLE 31. The method according to any of EXAMPLES 28 to 30,
wherein the scanning mirror (54) is arranged at a reference point (84) along the beam path,
wherein the beam path (41) of the light is optionally focused at the reference point (84).

EXAMPLE 32. The method according to any of EXAMPLES 28 to 31,
wherein the scanning of the light takes place with a scanning pattern selected from the following group: Cartesian scanning pattern; spiral scanning pattern; circular scanning pattern; elliptic scanning pattern; line scanning; one-dimensional scanning; two-dimensional scanning.

EXAMPLE 33. The method according to any of EXAMPLES 23 to 32, wherein the method furthermore comprises:
producing (3005) the master HOE (92) in a further exposure process,
wherein the carrier layer (91) of the master HOE (92) during the further exposure process has a first surface shape (911), which is different than a second surface shape (912) of the carrier layer
during the exposure process.

EXAMPLE 34. The method according to EXAMPLE 33,
wherein one (911, 912) out of the first surface shape and the second surface shape corresponds to a one-dimensional curvature of the carrier layer (91) of the master HOE (92),
wherein the other (912, 911) out of the first surface shape and the second surface shape corresponds to a planar embodiment of the carrier layer (91) of the master HOE (92).

EXAMPLE 35. The method according to any of EXAMPLES 23 to 34,
wherein the positioning module (56) comprises a robotic arm (231) with a plurality of adjustable axes.

EXAMPLE 36. The method according to any of EXAMPLES 23 to 34,
wherein the positioning module (56) comprises a multi-axis optical linear adjustment table (241, 242).

EXAMPLE 37. The method according to any of EXAMPLES 23 to 36,
wherein the positioning module is controlled on the basis of control data (401) determining the curved trajectory (61) and optionally an emergence angle (85) of the beam path (41) at the reference point in relation to the master HOE.

EXAMPLE 38. The method according to EXAMPLE 37,
wherein the control data (401) specify the angle (89) of incidence of the light on the master HOE.

EXAMPLE 39. The method according to EXAMPLE 37 or 38, wherein the method furthermore comprises:
calculating the control data (401) on the basis of a first surface shape (911) of the carrier material (91) of the master HOE (92) during a further exposure process for exposing the master HOE (92), and on the basis of a second surface shape (912) of the carrier material (91) of the master HOE (92) during the exposure process, and further on the basis of an angle (89) of incidence of light as a function of the location on the master HOE (92) during the further exposure process.

EXAMPLE 40. The method according to any of EXAMPLES 37 to 39, wherein the method furthermore comprises:
calculating the control data (401) on the basis of a geometry of a light source (851) which is used for reconstructing a hologram by illumination of the HOE.

EXAMPLE 41. The method according to any of EXAMPLES 37 to 40, wherein the method furthermore comprises:
calculating the control data (401) on the basis of a predefined aberration.

EXAMPLE 42. The method according to any of EXAMPLES 37 to 41, wherein the method furthermore comprises:
depending on the master HOE (92): selecting the control data (401) from a control data lookup table (400) comprising a multiplicity of candidate control data associated with different master HOEs.

EXAMPLE 43. The method according to any of EXAMPLES 23 to 42,
wherein at least one out of a shape of the trajectory (61), a scanning pattern and an angle of incidence of the light on the carrier material of the master HOE compensates for a curvature of the carrier material (91) of the master HOE (92) during the exposure process.

EXAMPLE 44. The method according to any of EXAMPLES 23 to 43,
wherein the carrier layer (95) of the HOE (96) has a second surface shape (912) during the exposure process,
wherein the method furthermore comprises:
after the exposure process: fixing (3015) the carrier layer of the HOE in a first surface shape (911), which is different than the second surface shape (912).

EXAMPLE 45. The method according to any of EXAMPLES 23 to 44, wherein the method furthermore comprises:
after fixing the carrier layer of the HOE, illumination of the HOE in order to reconstruct the hologram.

EXAMPLE 46. The method according to EXAMPLE 45,
wherein the illumination comprises with a light source with an areal geometry, such as, for example, an organic light emitting diode or a light emitting diode panel.

EXAMPLE 47. A computer program comprising program code which can be loaded and executed by a processor, wherein executing the program code causes the processor to carry out a method according to EXAMPLE 1 or EXAMPLE 23.

EXAMPLE 48. A method, comprising:
generating a holographic optical element, HOE, in a first surface shape, by replicating a master HOE,
fixing the HOE in a second surface shape, which is different than the first surface shape, and
after the fixing, illuminating the HOE with a light source, in order to reconstruct a hologram.

EXAMPLE 49. The method according to EXAMPLE 48,
wherein the light source is areal or comprises a light emitting diode panel.

It goes without saying that the features of the embodiments and aspects of the invention described above can be combined with one another. In particular, the features can be used not only in the combinations described but also in other combinations or on their own, without departing from the scope of the invention.

By way of example, various aspects in connection with a curved trajectory have been described. The trajectory can have this curvature in a global coordinate system, i.e. can be curved as viewed from outside (not only relatively in relation to the surface shape of the carrier layers of the master HOE and of the replicated HOE during replication). Generally, however, it would also be conceivable to use a straight trajectory. By way of example, comparable effects can be achieved with a suitable variation of the angle of incidence of the light on the carrier layer of the replicated HOE. Comparable effects can be achieved by the use of suitable scanning patterns.

Influences of aberrations and techniques for compensating for such influences have been discussed above on the basis of the example of a spherical aberration. However, it is also possible to take account of other aberrations described by corresponding Zernike polynomials.

A description has been given above of how different influences—for example different surface shapes 911, 912 during production of the master HOE, replication and system integration; different illumination geometries during exposure and illumination; aberrations-on the replication process and the reconstruction process can be taken into account. The various examples can also be combined with one another, which is helpful in particular in scenarios where the various effects occur in a superimposed manner—i.e. e.g. there is a specific curvature during system integration, but also aberrations on account of material shrinkage for instance during fixing for replicating the master HOE.

1. A method for producing a holographic optical element (HOE) by replicating a master HOE in the context of an exposure process, wherein a carrier layer (91) of the master HOE is arranged along a carrier layer of the HOE during the exposure process,
the method comprising:
controlling a radiation source in order to emit light onto the master HOE during the exposure process, with the result that the HOE is exposed, and
controlling a positioning module in order to move a reference point, which is arranged along a beam path of the light, in relation to the master HOE on a curved trajectory during the exposure process.

2. The method according to claim 1, wherein the positioning module is controlled in order to change an emergence angle of the beam path at the reference point in relation to the master HOE during the exposure process.

3. The method according to claim 1, wherein the method furthermore comprises controlling a scanning mirror in order to scan the light in relation to the master HOE during the exposure process.

4. The method according to claim 3, wherein a scanning direction during the scanning of a light point of the light on the master HOE during the exposure process has a component which is orthogonal to a movement direction of the light point of the light on the master HOE which is caused by the movement of the reference point along the curved trajectory.

5. The method according to claim 3, wherein the scanning of the light during the exposure process takes place with a fixed scanning frequency and optionally a fixed scanning amplitude.

6. The method according to claim 3, wherein the scanning mirror is arranged at the reference point, and wherein the beam path of the light is optionally focused at the reference point.

7-8. (canceled)

9. The method according to claim 1, wherein the method furthermore comprises: producing the master HOE in a further exposure process, wherein the carrier layer of the master HOE during the further exposure process has a first surface shape, which is different than a second surface shape of the carrier layer during the exposure process.

10. The method according to claim 9, wherein one out of the first surface shape and the second surface shape corresponds to a one-dimensional curvature of the carrier layer of the master HOE, and wherein the other out of the first surface shape and the second surface shape corresponds to a planar embodiment of the carrier layer of the master HOE.

11. (canceled)

12. The method according to claim 1, wherein at least one optical element is arranged at the reference point, having the effect that a light point of the light on the master HOE is expanded along at least one axis.

13. The method according to claim 1, wherein the positioning module comprises a robotic arm with a plurality of adjustable axes.

14. The method according to claim 1, wherein the positioning module comprises a multi-axis optical linear adjustment table.

15. The method according to claim 1, wherein the positioning module is controlled on the basis of control data specifying the curved trajectory and optionally an emergence angle of the beam path at the reference point in relation to the master HOE.

16. The method according to claim 14, wherein the control data specify an angle of incidence of the light on the master HOE.

17. The method according to claim 16, wherein the method furthermore comprises: calculating the control data on the basis of a first surface shape of the carrier material of the master HOE during a further exposure process for exposing the master HOE, and on the basis of a second surface shape of the carrier material of the master HOE during the exposure process, and further on the basis of an angle of incidence of light as a function of the location on the master HOE during the further exposure process.

18. The method according to claim 16, wherein the method furthermore comprises calculating the control data on the basis of a geometry of a light source which is used for reconstructing a hologram by illumination of the HOE.

19-20. (canceled)

21. The method according to claim 1, wherein the curved trajectory compensates for a curvature of the carrier material of the master HOE during the exposure process.

22. The method according to claim 1, wherein the carrier layer of the HOE has a second surface shape during the exposure process, and wherein the method furthermore comprises after the exposure process, fixing the carrier layer of the HOE in a first surface shape, which is different than the second surface shape.

23. A method for producing a holographic optical element, HOE by replicating a master HOE in the context of an exposure process, wherein a carrier layer of the master HOE is arranged along a carrier layer of the HOE during the exposure process, the method comprising:
controlling a radiation source in order to emit light onto the master HOE (92) during the exposure process, with the result that the HOE is exposed, and
controlling a positioning module in order to move a light point of the light over the carrier layer of the HOE during the exposure process and in order to expose the HOE at different positions of the light point on the carrier layer at different angles of incidence.

24. The method according to claim 23, wherein the positioning module is controlled in order to move a reference point, which is arranged along a beam path of the light, in relation to the master HOE on a trajectory during the exposure processm wherein the positioning module is controlled in order to change an emergence angle of the beam path at the reference point in relation to the master HOE during the exposure process.

25-44. (canceled)

45. The method according to claim 23, wherein the method furthermore comprises after fixing the carrier layer of the HOE, illumination of the HOE in order to reconstruct the hologram, wherein the illumination comprises the illumination with a light source with an areal geometry, such as, for example, an organic light emitting diode or a light emitting diode panel.

46-47. (canceled)

48. A method, comprising:
generating a holographic optical element, HOE, in a first surface shape, by replicating a master HOE,
fixing the HOE in a second surface shape, which is different than the first surface shape, and
after the fixing, illuminating the HOE with a light source, in order to reconstruct a hologram.

49. (canceled)
